(19) United States
(12) Patent Application Publication
(10) Pub. No.: US 2004/0026602 A1
(43) Pub. Date: Feb. 12, 2004

(54) Adjustable light converging device

(76) Inventor: Tsung-Yin Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,702

(22) Filed: Aug. 8, 2002

(51) Int. Cl. H01L 27/00

(52) U.S. Cl. 250/208.1

(57) ABSTRACT

A light converging device for a light source, which is suitable for use in an optical scan module. The light source has at least a lamp, while the light converging device has a lamp holder and an adjusting member. The lamp holder has an arc notch for holding the lamp, and the curvature of the arc notch can be adjusted freely. The adjusting member is mounted on the lamp holder for adjusting the curvature of the lamp holder.

### BACKGROUND OF THE INVENTION

1. Field of the Invention

The invention relates in general to a light converging device, and more particularly, to a light converging device applied to an optical scan module. The light converging device is operative to change the light converging effect, so as to adjust the irradiance radiated on a document to be scanned.

2. Description of Related Art

Scanners have become standard equipment for computer users scanning and inputting the texts or images of documents, magazines, books and pictures into a computer for further processing. Of the various kinds of scanners, the flatbed scanner is the most commonly applied one. In a flatbed scanner, the scan module (chassis) is installed to move back and forth under a transparent flat bed to scan the document on the transparent flat bed. The scan module itself does not include the driving power. Therefore, a transmission mechanism such as a step motor, gears and belt is required. While using a flatbed scanner to scan a document, the document is disposed on the transparent flat bed and covered by the lid of the scanner, such that the document can be pressed downward to the flatbed allowing the scan to be performed.

Referring to FIG. 1, a conventional optical scan module includes a light source module 110, a reflection mirror set 140, an optical lens 150, an optical sensor 160 and a carrier box 170. The light source module 110, the reflection mirror set 140, the optical lens 150 and the optical sensor 160 are all disposed in the carrier box 170. During the scanning process, the light source module 110 radiates on the document 120 on the transparent panel 130. An image is obtained through reflection. The reflection mirrors set 140 includes a plurality of reflection mirrors 140a, 140b and 140c disposed along the optical path to guide the image of the document 120 therein. The light of the image is then reflected from the reflection mirror set 140 into the optical lens 150. The optical lens is operative to receive and display the image of the document 120 transmitted by the reflection mirror set 140 to the optical sensor 160. The optical sensor 160, including a charge couple device (CCD), for example, is carried on a circuit board to be electrically connected thereto.

As shown in FIG. 2, the light source module 110 consists of a lamp 112 and a light converging device 140. The light converging device 114 includes a lamp holder 116 and a reflection mirror 118. The lamp holder 116 has an arc notch to accommodate the lamp 112. The reflection mirror 118 is disposed in the surface of the arc notch 119 of the lamp holder 116, such that the light beam emitted from the lamp 112 to the arc notch 119 is reflected to the document 120 by the reflection mirror 118.

In terms of scanning mechanisms, the higher the scan resolution is demanded, the larger the irradiance of the light source module radiated the document is required. Similarly, when a faster scanning speed is demanded, the larger the irradiance of the light source module is required. However, in the above light source module 110, if the irradiance emitted from the light source module 110 is constant, a low scanning speed has to be adapted when a high scanning resolution is selected. That is, the high scanning speed is only applicable to low scan resolution, so that the scanning efficiency cannot be enhanced. A conventional method to improve the irradiance of the document is proposed. The conventional method changes the voltage or current of the lamp to alter and adjust the luminance of the lamp, such that the irradiance of the document is adjusted. However, such method increases the fabrication cost of the lamps and shortens the lifetime thereof, which increases the application cost.

### SUMMARY OF INVENTION

The present invention provides a light converging device applicable in an optical scan module. By changing or adjusting the curvature of the reflection member in the light converging device, the irradiance of the light source module incident on the document can be changed or adjusted to enhance the efficiency of the scanner.

The present invention further provides a light converging device suitable for use in an optical scan module, which changes or adjusts the curvature of the reflection member of a light converging apparatus. Therefore, the irradiance of the light source module radiated on the document is changed or adjusted without using the expensive special designed lamp. The cost is thus reduced.

The adjustable light converging device provided by the present invention is suitable for use in a light source module. The light source module is applicable to a light scan module which comprises at least one lamp. The light converging device comprises a lamp holder and an adjusting member. The lamp holder has an arc notch for carrying the lamp. The curvature of the arc notch can be adjusted freely. The adjusting member is disposed on the lamp holder to adjust the curvature.

In one embodiment of the present invention, the lamp holder includes a first carrying member and a second carrying member. The second carrying member is hinged with the first carrying member. The second carrying member has a first gear structure. The space formed between the first and second carrying member is the above-mentioned arc notch.

In one embodiment of the adjustable light converging device, the adjusting member comprises a roller wheel which includes a second gear structure. The first gear structure of the second carrying member is engaged with the second gear structure of the roller. Therefore, the rotation of the roller can drive the second carrying member to rotate, so as to adjust the curvature of the arc notch of the lamp holder and the reflection member. As a result, the irradiance radiated on the document can be adjusted and altered.

Further, in another embodiment of the adjustable light converging device, the lamp holder can be made of bendable material to form the arc notch by bending the lamp holder. The lamp holder thus comprises two rigid strip members located at two sides of the axis of the lamp in parallel.

In addition, in each of the above embodiments, the adjusting member includes a sleeve, two lead screws, and a roller. The internal wall at two sides of the sleeve has a first screw thread and a second screw thread with volute along opposing directions. The external wall of the sleeve further comprises a third screw thread. Two lead screws are threaded into the sleeve from the first and the second screw threads. A external surface of the roller has a fourth screw thread engageable with the third screw thread of the sleeve. The ends of the lead screws are each equipped with the rigid strip member, allowing the adjusting member to be installed on the lamp holder. Thus, the rotation of the sleeve drives the lead screws to thread in or out, such that the curvature of the arc notch of the lamp holder and the reflection member can be adjusted to adjust and change the irradiance of the light beam incident on the document.

Further, the adjustable light converging device comprises a reflection member disposed on a surface of the arc notch to reflect the light beam emitted from the lamp. The curvature of the reflection member is consequently adjusted as the curvature adjustment of the arc notch.

Preferably, the reflection member can also be made of bendable material.

### BRIEF DESCRIPTION OF DRAWINGS

These, as well as other features of the present invention, will become more apparent upon reference to the drawings wherein:

FIG. 1 shows a cross sectional view of a conventional optical scan module;

FIG. 2 shows a side view of a light converging device of a conventional optical scan module;

FIG. 3 shows a cross sectional view of a light converging device in one embodiment of the present invention;

FIG. 4 shows a side view of a light converging device in one embodiment of the present invention;

FIG. 5 shows a schematic side view of a light converging device with a relatively low resolution in one embodiment of the present invention;

FIG. 6 shows a schematic side view of a light converging device with a relatively high resolution in one embodiment of the present invention;

FIG. 7 shows a front view of a light converging device in one embodiment of the present invention;

FIG. 8 shows a side view of a light converging device in one embodiment of the present invention;

FIG. 9 shows a schematic side view of a light converging device with a relatively low resolution in one embodiment of the present invention; and

FIG. 10 shows a schematic side view of a light converging device with a relatively high resolution in one embodiment of the present invention

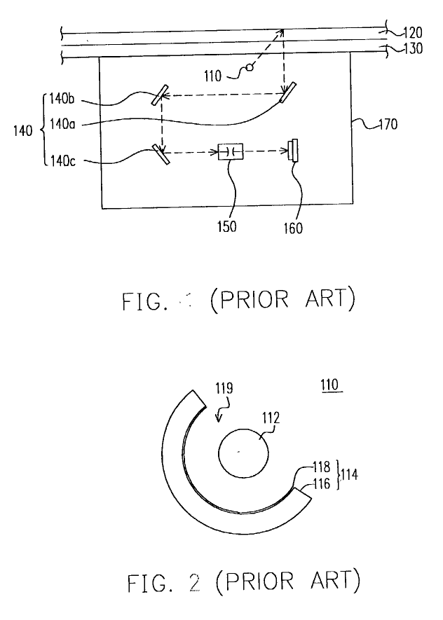

### DETAILED DESCRIPTION

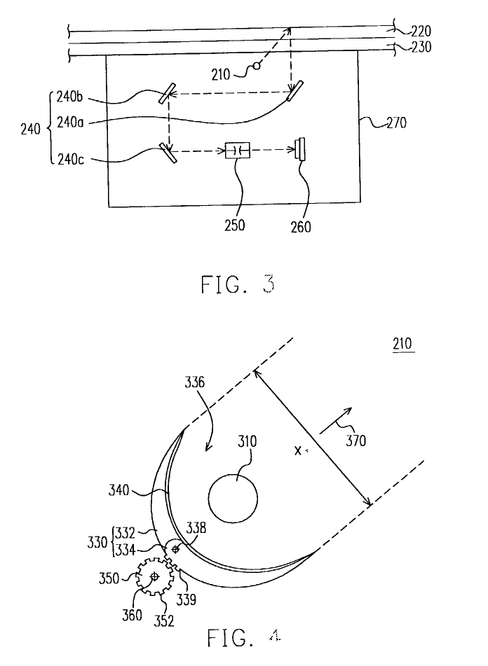

Referring to FIG. 3, a schematic cross sectional view of an optical scan module in one embodiment of the present invention is shown. The optical scan module 200 comprises a light source module 210, a reflection mirror set 240, an optical lens 250, a carrier box 270 and an optical sensor 260. The optical sensor includes a charge coupled device (CCD), for example. The light source module 210, the reflection mirror set 240, the optical lens 250 and the optical sensor 260 are disposed in the carrier box 270. While performing scan, the light source module 210 radiates a document 220 disposed on a transparent panel 230 to obtain an image light by way of reflection. The reflection mirror set 240 including a plurality of reflection mirrors (240a, 240b, 240c) is disposed along an optical path of the image light, so that the image of the document 220 is directed into the reflection mirror set 240 and then reflected to the optical lens 250 therefrom. The optical lens 250 displays the image light transmitted from the reflection mirror set 240 on the optical sensor 260.

Referring to FIG. 4, a schematic side view of a light converging device in one embodiment of the present invention is shown. In this embodiment, the light converging device and a lamp 310 constitute the light source module 210 as shown in FIG. 3. The light converging device comprises a lamp holder 330 and an adjusting member.

The lamp holder 330 comprises a first carrying member 332 and a second carrying member 334. The first carrying member 332 is pivotally connected to the second carrying member 334 by a hinge 338, such that the second carrying member 334 can freely rotate relative to the first carrying member 332. Further, a space withheld by the first carrying member 332 and the second carrying member 334 forms an arc notch 336. As shown in FIG. 4, the second carrying member 334 has a first gear structure 339 thereon. The first gear structure 339 is disposed on an edge region of the second carrying member 334 distal to the arc notch 336.

The adjusting member includes a roller wheel 350, for example. The roller wheel 350 is mounted to a pivot 360. A second gear structure 352 engaged with the first gear structure 339 is formed at the periphery of the roller wheel 350. The pivot is further connected to a driving device such as a motor (not shown). Being driven by the driving device, the roller wheel 350 rotates to drive the second carrying member 334 to rotate about the hinge 338.

The light converging device further comprises a reflection member 340 disposed on the edge lamp holder 330 along the arc notch 336, allowing the light beam emitted from the lamp 310 to be reflected to the document. The material for forming the reflection member 340 includes bendable material. When the second carrying member 334 rotates to adjust the size and the curvature of the arc notch 336, the bendable reflection member 340 is still attached to the edge of the lamp holder 330. On the other hand, the bending level of the reflection member 340 reflects the curvature of the arc notch 336.

Referring to FIG. 5, a schematic side view of a light converging device with a relatively low resolution is shown. When a relatively low resolution is required for scanning a document, driven by the driving device, the roller wheel 350 rotates counterclockwise along the arrow 380. Consequently, the second carrying member 334 engaged with the roller wheel 350 rotates clockwise around the pivot 338 along the arrow 390 as shown in FIG. 5. Compared to FIG. 4, the arc notch 336 of the lamp holder 330 has a smaller curvature and a larger opening. Therefore, the light beam 370 emitted from the lamp radiates the document within a radiation range X₂, and the radiation range X₂ is larger than the radiation range X₁ as shown in FIG. 4. With the same emission intensity of the lamp 310, the light converging effect in FIG. 5 is poorer. The lower irradiance of the lamp 310 radiating on the document is suitable for scanning a document with a low resolution.

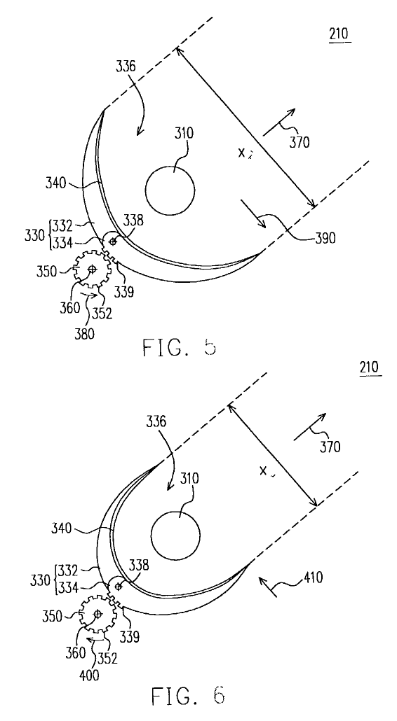

Referring to FIG. 6, a schematic side view of a light converging device with a relative high resolution is shown. When a relatively high resolution is required for scanning a document, driven by the driving device, the roller wheel 350 rotates clockwise along the arrow 400. Consequently, the second carrying member 334 engaged with the roller wheel 350 rotates counterclockwise around the pivot 338 along the arrow 410 as shown in FIG. 6. Compared to FIG. 4, the arc notch 336 of the lamp holder 330 has a larger curvature and a smaller opening. Therefore, the light beam 370 emitted from the lamp radiates the document within a radiation range X₃, and the radiation range X₃ is smaller than the radiation range X₁ as shown in FIG. 4. With the same emission intensity of the lamp 310, the light converging effect in FIG. 6 is better. The lower irradiance of the lamp 310 radiating on the document is suitable for scanning a document with a high resolution. The irradiance of the lamp 310 radiating on the document is increased, so that a higher irradiance of the light beam incident on the optical sensor after being reflected by the document is increased. As a result, the time that the optical sensor 260 spends on detecting the image of the document is shortened. Therefore, while performing high-resolution scan on a document, the same scanning speed used for the low-resolution scan can be applied. The scanning speed is thus increased, and the performance of the scanner is enhanced.

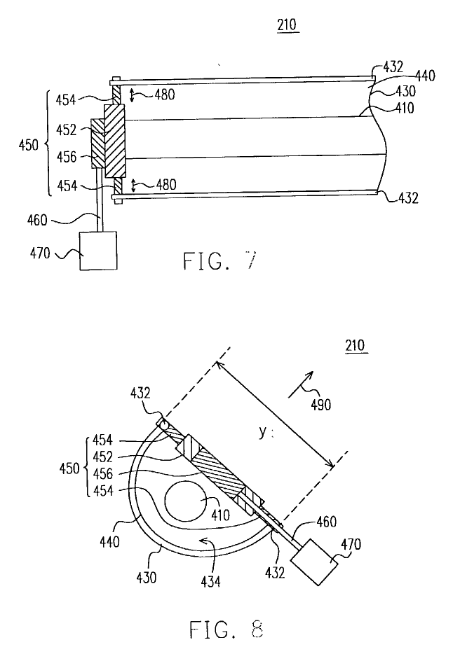

Referring to both FIGS. 7 and 8, FIG. 7 shows a front view of a converging device in another embodiment of the present invention, and FIG. 8 shows a side view of the converging device. In this embodiment, the light converging device and the lamp 410 constitute the light source module 210 as shown in FIG. 3. The light converging device comprises a lamp holder 430 and an adjusting member 450.

The adjusting member 450 comprises a sleeve 452, lead screws 454 and a roller 456. The interior wall at two ends of the sleeve 452 comprises a first screw thread and a second screw thread (not shown) directed opposite to each other. The exterior wall of the sleeve 452 has a third screw thread. The lead screws 454 are threaded into the sleeve 452 by matching the first and second screw threads, respectively. When the sleeve 452 is rotated, the lead screws are threaded in or out of the sleeve 452 along the direction 480 simultaneously. The roller 456 has a fourth screw thread to be engaged with the third screw thread of the sleeve 452. The pivot 460 of the sleeve 456 is connected to a driving device 470. The driving device 470 includes a motor to rotate the roller 456, for example.

The lamp holder 430 can be made of bendable material as a plate structure. The lamp holder 430 is bent to form the arc notch 434, allowing the lamp 410 to be accommodated therein. Rigid stripe structures 432 are formed at two sides of the lamp holder 430 parallel to the axis of the lamp 410. One side of each rigid stripe structure 432 is connected to the end of the one lead screw 454.

Further, the light converging device in this embodiment further comprises a reflection member 440 located on a surface along the arc notch 434. The reflection member 440 is used to reflect the light beam emitted from the lamp 410 onto the document. The material of the reflection member 440 includes bendable material. When the curvature and the opening of the lamp holder 430 is adjusted to cause the change of the curvature and the opening of the arc notch 434, the curvature of the reflection member 440 is consequently changed.

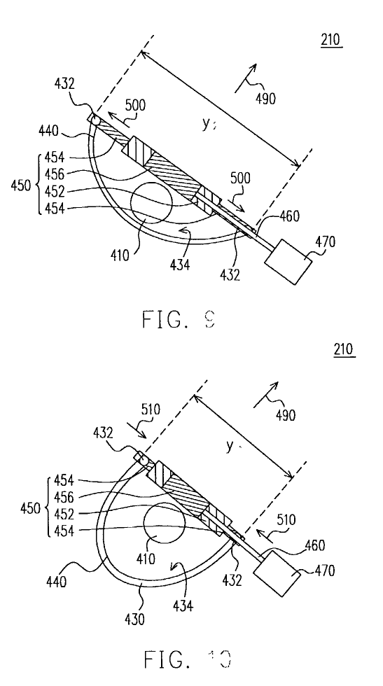

Referring to FIG. 9, a light converging device used for low scan resolution in another embodiment is illustrated. When a relatively low resolution is demanded, the roller 456 is rotated driven by the driving device 470. The sleeve 452 engaged with the roller 456 is also rotated to simultaneously move the lead screws 454 outwardly (along the direction 500). Compared to FIG. 8, the opening of the arc notch 434 of the lamp holder 430 is smaller to result in a larger curvature thereof. Therefore, the light beam 490 emitted by the lamp 410 radiates the document within the radiation range y₂. With the same luminance of the lamp 410, the adjustment of the light converging device allows the radiation range y₂ in FIG. 9 to be larger than the radiation range y₁ in FIG. 8. Under the same conditions, the light converging effect in FIG. 9 is poorer. The irradiance of the lamp 410 radiating on the document is lower, it is thus suitable for scanning a document with a lower resolution.

Referring to FIG. 10, a light converging device used for high scan resolution in another embodiment is illustrated. When a relatively high resolution is demanded, a first roller 456, driven by the driving device 470, is rotated along a direction opposite to that as shown in FIG. 9. A second roller 452 engaged with the first roller 456 is also rotated to simultaneously move the lead screws 454 (along the direction 510) into the first roller 452. Compared to FIG. 8, the opening of the arc notch 434 of the lamp holder 430 is larger to result in a smaller curvature thereof. Therefore, the light beam 490 emitted by the lamp 410 radiates the document within the radiation range y₃. With the same luminance of the lamp 410, the adjustment of the light converging device allows the radiation range y₃ in FIG. 9 to be smaller than the radiation range y₁ in FIG. 8. Under the same conditions, the light converging effect in FIG. 9 is more superior. The irradiance of the lamp 410 radiating on the document is increased, such that a higher irradiance of the light beam reflected from the document to the optical sensor is obtained. The time the optical sensor spends detecting the image of the document is shortened. Therefore, even when performing a high-resolution scan on the document, the scanning speed is enhanced. Consequently, the scanning performance of the scanner is improved.

According to the above, the adjustable light converging device alters or adjusts the curvature of the arc notch of the lamp holder, which consequently adjusts the curvature of the bendable reflection member mounted on a surface along the arc notch, so as to change the light converging effect. In addition, the irradiance radiating on the document can be changed or adjusted. Therefore, for different scan conditions, particularly the high-resolution scan, an adequate irradiance can be provided. Further, the present invention allows the high-resolution scan to scan a document with a scanning speed as fast as that of the low-resolution scan, the scanning speed can thus be optimized; while the performance of the scanner is enhanced.

Further, the structure improvement of the light converging device allows for adjusting the irradiance radiating on the document without changing the luminance of the lamp. Therefore, the expense of a special designed lamp is spared, so that the product cost is reduced.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

1. An adjustable light converging device, suitable for use in a light source module applied to an optical scan module, wherein the light source module has at least a lamp, the adjustable light converging device comprising:
a lamp holder, including an arc notch therein for carrying the lamp, wherein the curvature of the arc notch is adjustable; and
an adjusting member, mounted to the lamp holder to adjust the curvature of the arc notch.

2. The adjustable light converging device according to claim 1, wherein the light converging device further comprises a reflection member located on a surface along the arc notch to reflect light emitted from the lamp, and the curvature of the reflection member is consequently adjusted when the curvature of the arc notch is adjusted.

3. The adjustable light converging device according to claim 2, wherein the reflection member is made of bendable material.

4. The adjustable light converging device according to claim 1 , wherein the lamp holder further comprises:
a first carrying member; and
a second carrying member hinged over the first carrying member, wherein a space between the first and second carrying members construct the arc notch.

5. The adjustable light converging device according to claim 4, wherein the adjusting member further comprises a roller wheel which has a second gear structure, and the second carrying member has a first gear structure to be engaged with the second gear structure.

6. The adjustable light converging device according to claim 1, wherein the lamp holder is made of bendable material, and the lamp holder is bent to form the arc notch, the lamp holder further comprises two rigid stripe members mounted at two sides of the lamp holder parallel to an axis of the lamp.

7. The adjustable light converging device according to claim 6, wherein the adjusting member comprises:
a sleeve, having a first and a second screw thread on an interior wall at two ends thereof directed opposite to each other, and a third screw thread on an exterior wall thereof;
two lead screws, to be threaded into the sleeve via the first and the second screw threads; and
a roller, having a fourth screw thread is formed on a periphery thereof, wherein the fourth screw thread is engaged with the third screw thread;
wherein the ends of the lead screws are located at the rigid stripe members to mount the adjusting member to the lamp holder.

8. A light source module, suitable for use in an optical scan module, comprising:
a lamp; and
an adjustable light converging device, comprising:
a lamp holder, having an arc notch therein to carry the lamp, wherein the curvature of the arc notch can be adjusted freely; and
an adjusting member, mounted to the lamp holder to adjust the curvature of the arc notch.

9. The light source module according to claim 8, wherein the adjustable light converging device further comprises a reflection member located on a surface along the arc notch to reflect light emitted from the lamp, and the curvature of the reflection member is consequently adjusted when the curvature of the arc notch is adjusted.

10. The light source module according to claim 9, wherein the reflection member is made of bendable material.

11. The light source module according to claim 8, wherein the lamp holder further comprises:
a first carrying member; and
a second carrying member hinged over the first carrying member, wherein a space between the first and second carrying members constructs the arc notch.

12. The light source module according to claim 11, wherein the adjusting member further comprises a roller wheel which has a second gear structure, and the second carrying member has a first gear structure to be engaged with the second gear structure.

13. The light source module according to claim 8, wherein the lamp holder is made of bendable material, and the lamp holder is bent to form the arc notch, the lamp holder further comprises two rigid stripe members mounted at two sides of the lamp holder parallel to an axis of the lamp.

14. The light source module according to claim 13, wherein the adjusting member comprises:
a sleeve, having a first and a second screw thread on an interior wall at two ends thereof directed opposite to each other, and a third screw thread on an exterior wall thereof;
two lead screws, to be threaded into the sleeve via the first and the second screw threads; and
a roller, having a fourth screw thread is formed on a periphery thereof, wherein the fourth screw thread is engaged with the third screw thread;
wherein the ends of the lead screws are located at the rigid stripe members to mount the adjusting member to the lamp holder.

15. An optical scan module for scanning a document, comprising:
a carrier box;
a light source module, installed in the carrier box to radiate the document to obtain an image light, the light source module comprising:
a lamp; and
an adjustable light converging device, comprising:
a lamp holder, having an arc notch therein to carry the lamp, wherein the curvature arc notch can be adjusted freely; and
an adjusting member, mounted to the lamp holder to adjust the curvature of the arc notch;
a reflection mirror set, installed in the carrier along an optical path of the image light;
an optical lens, located along the optical path after the image light being reflected from the reflection mirror set; and
an optical sensor, fixed on a circuit board along the optical path of the image light being transmitted through the optical lens.

16. The optical scan module according to claim 15, wherein the adjustable light converging device further comprises a reflection member located on a surface along the arc notch to reflect light emitted from the lamp, and the curvature of the reflection member is consequently adjusted when the curvature of the arc notch is adjusted.

17. The optical scan module according to claim 16, wherein the reflection member is made of bendable material.

18. The optical scan module according to claim 15, wherein the lamp holder further comprises:
a first carrying member; and
a second carrying member hinged over the first carrying member, wherein a space between the first and second carrying members constructs the arc notch.

19. The optical scan module according to claim 18, wherein the adjusting member further comprises a roller wheel which has a second gear structure, and the second carrying member has a first gear structure to be engaged with the second gear structure.

20. The optical scan module according to claim 15, wherein the lamp holder is made of bendable material, and the lamp holder is bent to form the arc notch, the lamp holder further comprises two rigid stripe members mounted at two sides of the lamp holder parallel to an axis of the lamp.

21. The optical scan module according to claim 20, wherein the adjusting member comprises:
a sleeve, having a first and a second screw thread on an interior wall at two ends thereof directed opposite to each other, and a third screw thread on an exterior wall thereof;
two lead screws, to be threaded into the sleeve via the first and the second screw threads; and
a roller, having a fourth screw thread is formed on a periphery thereof, wherein the fourth screw thread is engaged with the third screw thread;
wherein the ends of the lead screws are located at the rigid stripe members to mount the adjusting member to the lamp holder.
